(19) United States
(12) Patent Application Publication
(10) Pub. No.: US 2016/0055909 A1
(43) Pub. Date: Feb. 25, 2016

(54) Integrated Circuit Comprising an Input Transistor Including a Charge Storage Structure

(71) Applicant: Infineon Technologies Austria AG, Villach (AT)

(72) Inventors: Jens Barrenscheen, Muenchen (DE); Anton Mauder, Kolbermoor (DE)

(21) Appl. No.: 14/828,738

(22) Filed: Aug. 18, 2015

(30) Foreign Application Priority Data
Aug. 21, 2014 (DE) 102014112001.9

(51) Int. Cl. G11C 16/04; G11C 16/06

(52) U.S. Cl. CPC G11C 16/0408; G11C 16/06

(57) ABSTRACT

An electronic circuit comprises an input insulated gate field effect transistor. The input insulated gate field effect transistor comprises first and second load terminals and a control terminal. The control terminal is electrically coupled to an input signal terminal of the electronic circuit. The electronic circuit further comprises a control circuit. An input terminal of the control circuit is electrically coupled to the second load terminal. The control terminal is electrically connected to a control structure comprising a control electrode and charge storage structure.

### BACKGROUND

Voltage detection is a key feature of integrated circuit applications such as power supplies or switches. Typically, resistive dividers and/or zener diodes or avalanche diodes are used for voltage detection. Design of voltage dividers is challenging in view of voltage detection characteristics such as losses, precision and speed of voltage detection.

It is desirable to provide an electronic circuit having improved voltage detection characteristics and to provide a method of evaluating an input voltage signal.

### SUMMARY

According to an embodiment of an electronic circuit, the electronic circuit comprises an input insulated gate field effect transistor. The input insulated gate field effect transistor comprises first and second load terminals and a control terminal. The control terminal is electrically coupled to an input signal terminal of the electronic circuit. The electronic circuit further comprises a control circuit. An input terminal of the control circuit is electrically coupled to the second load terminal. The control terminal is electrically connected to a control structure comprising a control electrode and charge storage structure.

According to another embodiment of an electronic circuit, the electronic circuit comprises a plurality of input insulated gate field effect transistors. Each of the input insulated gate field effect transistors comprises first and second load terminals and a control terminal. The control terminals of the plurality of input insulated gate field effect transistors are electrically coupled to an input signal terminal of the electronic circuit. The electronic circuit further comprises a control circuit electrically coupled to the second load terminals. Each of the control terminals is electrically connected to a control structure comprising a control electrode and charge storage structure.

Another embodiment relates to a method of evaluating an input voltage signal. The method comprises detecting the input voltage signal active current-free by applying the input voltage signal to a control terminal of at least one input insulated gate field effect transistor, wherein a control structure of the least one input insulated gate field effect transistor comprises a control electrode and charge storage structure. The method further comprises supplying a control circuit with a signal at the load terminal of the at least one input insulated gate field effect transistor.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the invention and are incorporated in and constitute a part of this specification. The drawings illustrate the embodiments of the present invention and together with the description serve to explain principles of the invention. Other embodiments of the invention and intended advantages will be readily appreciated as they become better understood by reference to the following detailed description.

FIG. 1 is a schematic illustration of an electronic circuit according to an embodiment.

FIG. 2A is a schematic cross-sectional view of a portion of a semiconductor switching device of the electronic circuit of FIG. 1 according to an embodiment.

FIG. 2B are schematic IL/VGS characteristics for discussing effects of embodiments concerning normally-off semiconductor switching devices.

FIG. 2C is a schematic cross-sectional view of a portion of the semiconductor switching device of FIG. 1 according to another embodiment.

FIG. 3 is a schematic illustration of another embodiment of an electronic circuit including a semiconductor switching device and a comparator.

FIG. 4 is a schematic illustration of another embodiment of an electronic circuit including a plurality of semiconductor switching devices electrically coupled to a control circuit.

FIG. 5 is a schematic illustration of another embodiment of an electronic circuit configured for active current-free voltage detection at a primary side of a switch-mode power supply (SMPS) or a power factor correction or power factor compensation (PFC) circuit.

FIG. 6 is a schematic chart illustrating a method of evaluating an input voltage signal.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open and the terms indicate the presence of stated structures, elements or features but not preclude the presence of additional elements or features. The articles “a”, “an” and “the” are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor. The term “electrically coupled” includes that one or more intervening element(s) adapted for signal transmission may exist between the electrically coupled elements, for example elements that temporarily provide a low-ohmic connection in a first state and a high-ohmic electric decoupling in a second state.

The Figures illustrate relative doping concentrations by indicating “−” or “+” next to the doping type “n” or “p”. For example, “n−” means a doping concentration that is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

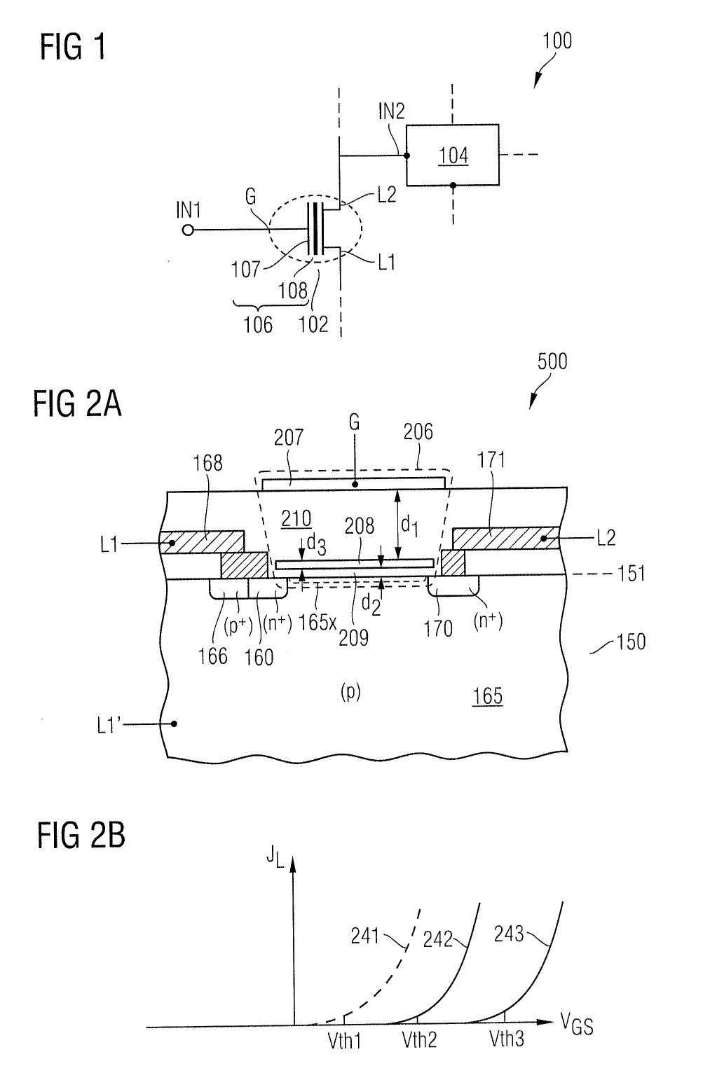

An embodiment of an electronic circuit 100 is schematically illustrated in FIG. 1. The electronic circuit 100 comprises an input insulated gate field effect transistor 102 comprising first and second load terminals L1, L2 and a control terminal G. The control terminal is electrically coupled to an input signal terminal IN1 of the electronic circuit 100. The electronic circuit 100 further comprises a control circuit 104. An input terminal IN2 of the control circuit 104 is electrically coupled to the second load terminal L2. The control terminal G is electrically connected to a control structure 106 comprising a control electrode 107 and a charge storage structure 108.

The electronic circuit 100 is configured to perform active current-free voltage detection by applying an input voltage signal to the control terminal G of the input insulated gate field effect transistor 102.

In the embodiment illustrated in FIG. 1, dashed lines indicate interconnections with further circuit elements, for example other functional circuit blocks or devices and circuit pins.

An amount of charge inserted into the charge storage structure 108 allows for an adjustment of a threshold′ voltage of the input insulated gate field effect transistor 102. When a voltage between the control terminal G and the first load terminal L1 exceeds the threshold voltage, the input insulated gate field effect transistor 102 is turned on and a variation of the voltage at the second load terminal L2 due to an increase of the voltage above the threshold voltage at the control terminal G can be detected and analyzed via the control circuit 104. The control circuit 104 may then initiate any desired function such as, for example, a protection function in high-voltage switches or a stabilization function of a supply voltage, or analog to digital conversion, or any other function that is to be initiated by detecting a voltage change with respect to a threshold voltage.

Since the threshold voltage can be set to high values exceeding several hundreds of volts or even more than thousand volts with high precision, a number of benefits can be achieved compared with known resistive dividers having a division ratio of n:1. The active current-free voltage detection of the embodiment illustrated in FIG. 1 does not suffer from resistive losses typical for resistive dividers. Further, division ratios of n:1, n>>1, lead to an amplification of any variations of the threshold to be detected by a factor of n. For avoiding a distortion of the threshold to be detected by leakage current(s) and/or cross current(s), high impedance inputs may be required in electronic circuits evaluating the divided voltage of resistive dividers. This may lead to an increased susceptibility, for example to an increased electromagnetic susceptibility which may be counteracted by placing a capacitor in parallel to the input of a threshold detection circuit. This, on the other hand, results in a low-pass filter which may have a negative impact on the speed of threshold detection. In other words, the speed of response of the threshold detection circuit, i. e. the charging time of the capacitor, is directly linked to the resistor value of the resistive divider and thus to the losses caused by the resistive divider. Above drawbacks which have to be dealt with in resistive dividers are less pronounced or do not even arise in the electronic circuit of FIG. 1.

According to an embodiment, the input insulated gate field effect transistor 102 is a normally off n-type channel insulated gate field effect transistor (normally off n-IGFET). According to other embodiments, the input insulated gate field effect transistor 102 is a normally on n-type channel insulated gate field effect transistor (normally on n-IGFET), a normally off p-type channel insulated gate field effect transistor (normally off p-IGFET) or a normally on p-type channel insulated gate field effect transistor (normally on p-IGFET).

According to an embodiment, a threshold voltage of the input insulated gate field effect transistor 102 is at least 10 times greater than a threshold voltage of an insulated gate field effect transistor of the control circuit 104. The control circuit 104 may include low voltage insulated gate field effect transistors typically employed in logic circuits, for example having threshold voltages smaller than 10 V. Contrary thereto, the threshold voltage of the input insulated gate field effect transistor 102 allows for a detection of greater voltages, for example voltages greater than 40 V, 60V, 80 V, 100 V, 250 V, 500 V, 750 V, 1000 V.

According to an embodiment, the input insulated gate field effect transistor 102 and the control circuit 104 are monolithically integrated. The input insulated gate field effect transistor 102 and the control circuit 104 may be formed in one semiconductor substrate, for example in one semiconductor wafer or in a die diced from a semiconductor wafer.

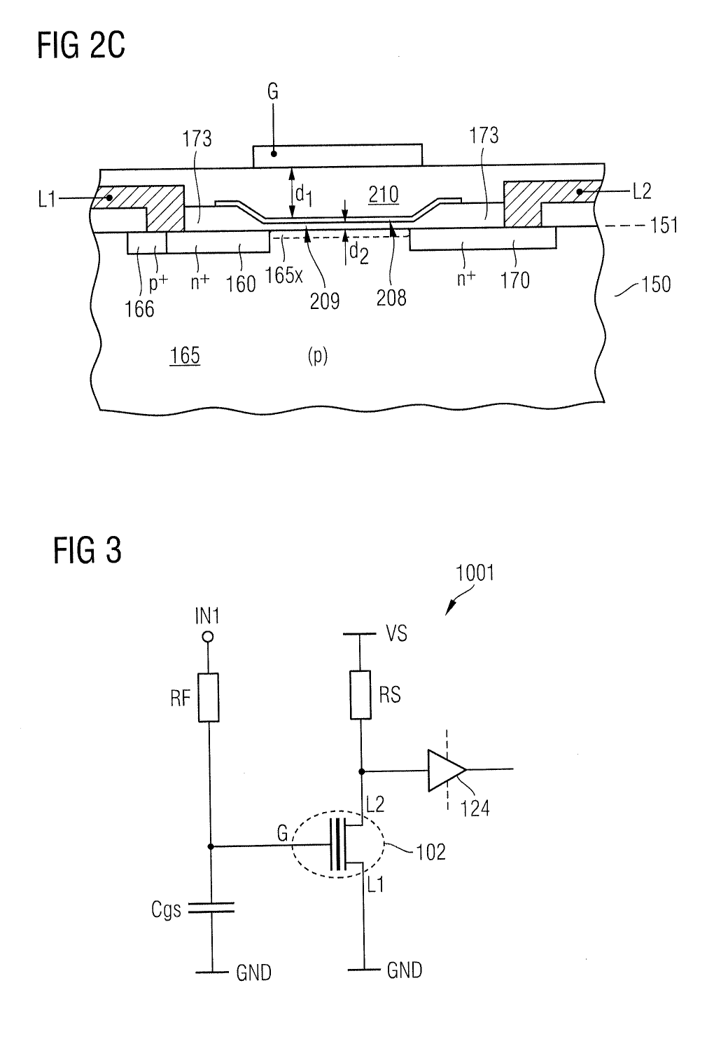

With reference to FIGS. 2A, 2B, and 2C embodiments of the input insulated gate field effect transistor 102 of the electronic circuit 100 of FIG. 1 will be described based on cross-sectional views.

FIG. 2A refers to a semiconductor switching device 500 such as an IGFET (insulated gate field effect transistor), for example a MOSFET (metal oxide semiconductor FETs) in the usual meaning including FETs with metal gates as well as FETs with non-metal gates.

The semiconductor switching device 500 is based on a semiconductor body 150 from a single-crystalline semiconductor material such as silicon (Si), silicon carbide (SiC), germanium (Ge), a silicon-germanium crystal (Site), gallium nitride (GaN), gallium arsenide (GaAs) or any other AIIlBV semiconductor. The semiconductor body 150 has a first surface 151 which may be approximately planar or which may be defined by a plane spanned by coplanar surface sections. A direction perpendicular to the first surface 151 defines a vertical direction and directions orthogonal to the vertical direction are horizontal directions. In a horizontal plane the semiconductor body 150 may have a rectangular shape with an edge length in the range of several hundreds of micrometers (pm), millimeters (mm) or centimeters (cm) typical for dies diced from a wafer or may be disc-shaped with a diameter of several centimeters.

A transistor cell in the semiconductor body 150 includes a source zone 160 of a first conductivity type directly adjoining the first surface 151. The source zone 160 adjoins a body zone 165 having a second, complementary conductivity type. The first load terminal L1 is electrically connected to the source zone 160 and optionally to the body zone 165 via a first wiring 168. An optional, highly doped body contact zone of the second conductivity type may improve an electrical connection between the body zone 165 and the first load terminal L1. In other words, the first wiring 168 may form an electrical contact with the source zone 160 and the body zone 165 as shown in FIG. 2A or may form a contact only to the source zone 160 (not shown in FIG. 2A). In case the body zone 165 is not connected to the first load terminal L1, it may be connected to a further terminal L1′. The first wiring 168 may include through hole contact(s) and a part of patterned interconnection level(s) such as one or more conductive lines. A drain zone 170 of the first conductivity type adjoins the body zone 165. The second load terminal L2 is electrically connected to the drain zone 170 via a second wiring 171. Similar to the first wiring 168, the second wiring 171 may include through hole contact(s) and a part of patterned interconnection level(s) such as one or more conductive lines. A control structure 206 directly adjoins the body zone 165. The control structure 206 includes a control electrode 207 and a charge storage structure 208. A tunnel dielectric 209 is arranged between the charge storage structure 208 and the semiconductor body 150. A gate dielectric 210 is arranged between the control electrode 207 and the charge storage structure 208. A thickness d1 of the gate dielectric 210 is adjusted in consideration of a maximum blocking voltage during operation of the semiconductor switching device 500. For silicon oxide, typical electric field strengths, depending on the quality of the oxide, are in the range of MV/cm. This results in a thickness d1 at a blocking voltage of 450 V in the range of 0.15 to several μm, e.g. thicker than 0.15 μm, thicker than 0.4 μm, thicker than 0.8 μm, or thicker than 1.2 μm and thinner than 30 μm, thinner than 20 μm, thinner than 15 μm, thinner than 10 μm, thinner than 8 μm, or thinner than 6 μm. Higher blocking voltages require a greater thickness d1. Likewise, lower blocking voltages require a smaller thickness d1. A typical thickness d2 of the tunnel dielectric 209 in case of a thermal oxide ranges between 3 nm and 15 nm.

According to an embodiment, the charge storage structure 208 is one of a floating gate electrode, for example a polycrystalline silicon floating gate electrode, and a silicon nitride layer. The silicon nitride layer may be grown or deposited in an oven process, for example. A minimum thickness of the silicon nitride layer may be defined by a charge density to be achieved as well process technological constraints, for example. Assuming a maximum charge density in the silicon nitride of 1019/cm3, a surface charge of the silicon nitride of around 1013/cm2 requires a minimum thickness of around 2 nm. A typical thickness of the silicon nitride layer is in the range of one or several tens of nm. A typical thickness d3 of the polycrystalline silicon floating gate electrode is in the range of several tens of nm to approximately 1 μm.

After manufacturing the semiconductor switching device 500 and measuring the threshold voltage Vth, applying a voltage to the control electrode 206 with respect to the source, body and drain zones 160, 165, 170 allows to charge the charge storage structure 208 with electrons. In case of an n-IGFET, applying a positive voltage to the control electrode 206 with respect to the source, body and drain zones 160, 165, 170 allows to charge the charge storage structure 208 with electrons. Measuring the threshold voltage and altering a charge of the charge storage structure 208 as described above may be repeated one or several times to adjust the threshold voltage Vth to a target value. An example of a typical charging time of the charge storage structure 208 lies in the ms range.

Dimensions and materials of elements of the control structure 206 may be chosen in consideration of a desired voltage blocking capability of the semiconductor switching device 500.

The above examples are merely numerical examples to receive an impression of certain dimensions of elements of the semiconductor switching device 500.

The control electrode 207 is capacitively coupled to the body zone 165 such that in a channel portion 165x of the body zone 165 an inversion channel may be switched on and off by varying a potential applied between the control terminal G and the first load terminal L1 and/or the further load terminal L1′, respectively. Through the inversion channel a load current flows between the first and second load terminals L1, L2 in an on state of the semiconductor switching device 500.

In FIG. 2B IL/VGS characteristics 241, 242, 243 illustrate the load current IL as a function of the gate-to-source voltage VGS applied between the control terminal G and the

first load terminal L1 of a normally-off semiconductor switching device at a constant drain to source voltage VDS assuming body zone 165 and source zone 160 being on the same electrical potential. The normally-off device starts to conduct a load current IL at VGS=Vth1.

When increasing the negative control charge in the charge storage structure 208 of the semiconductor switching device 500 the control structure 206 is biased such that a threshold voltage Vth shifts to higher values, for example from Vth1 for IL/VGS characteristic 241 to Vth2 for IL/VGS characteristic 242 and to Vth3 for IL/VGS characteristic 243.

FIG. 2C illustrates a semiconductor switching device 600 that differs from the semiconductor switching device 500 illustrated in FIG. 2A with respect to an arrangement of the first and second wirings 168, 171 to the channel portion 165x. In the semiconductor switching device 600, a lateral distance between each of the first and second wirings 168, 171 and the channel portion 165x is increased with respect to the semiconductor switching device 500 for reasons of increased and reliable blocking voltage capability. The charge storage structure 208 may overlap a field dielectric layer 173 on the source and drain zones 160, 170. According to another embodiment, the charge storage structure 208 may also end on the tunnel dielectric 209 as is illustrated in FIG. 2A. This may allow for benefits in processing such as self-aligned ion implantation of dopants of the source and drain zones 160, 170 masked by the charge storage structure 208, for example.

Since comparatively low voltages appear between the source and drain zones 160, 170, for example voltages which are typical for logic circuits in the range of some volts, several IGFETs having, as an option, different threshold voltages may be monolithically integrated in one semiconductor die or chip. By way of example, for an n-IGFET, the source zone 160 may be electrically coupled to a most negative reference voltage such as ground (GND) and the drain zone 170 may be electrically coupled via open drain terminals.

Since the threshold voltage can be adjusted, for example as described above with reference to FIG. 2A, different threshold voltage levels can be easily realized. Thus, product test equipment of chip manufacturers allows for realization of different product variants based one front-end-of-line (FEOL) process, for example.

The embodiments described with reference to FIGS. 2A, 2C include planar gate structures. According to other embodiments, the control structure 106 of the input insulated gate field effect transistor 102 of FIG. 1 may also be formed in a trench, for example in a trench of a vertical trench transistor having the first and second load terminals at opposite sides of the semiconductor body leading to a vertical load current flow, i.e. a load current flow along a vertical direction perpendicular to the first and second sides.

Another embodiment of an electronic circuit 1001 is schematically illustrated in FIG. 3. The electronic circuit 1001 comprises the input insulated gate field effect transistor 102. Examples of cross-sectional views of the input insulated gate field effect transistor 102 are described with reference to FIGS. 2A to 2C.

Since a resistance between source and drain of input insulated gate field effect transistor 102 substantially changes when reaching the threshold voltage Vth applied between gate and source, a simple evaluation circuit may be applied for voltage detection.

A capacitor Cgs illustrated in FIG. 3 represents an internal gate to source capacitance of the input insulated gate field effect transistor 102. When the control terminal G is not directly connected to the input signal terminal IN1 but electrically coupled to the input signal terminal IN1 via a resistor RF, a filter function can be achieved over a wide operation range. This allows for a better suppression of disturbances, for example. A time constant RF×Cgs of the filter can be adjusted independent of electric loss considerations. Optionally, an additional, integrated and/or external capacitor may be connected in parallel to the control terminal G and the first load terminal L1 in order to change the filter function.

The second load terminal L2 is electrically coupled to a comparator 124 being an exemplary part of the control circuit 104 illustrated in FIG. 1. Further, the second load terminal L2 is electrically coupled to a supply voltage terminal VCC via a resistor RS.

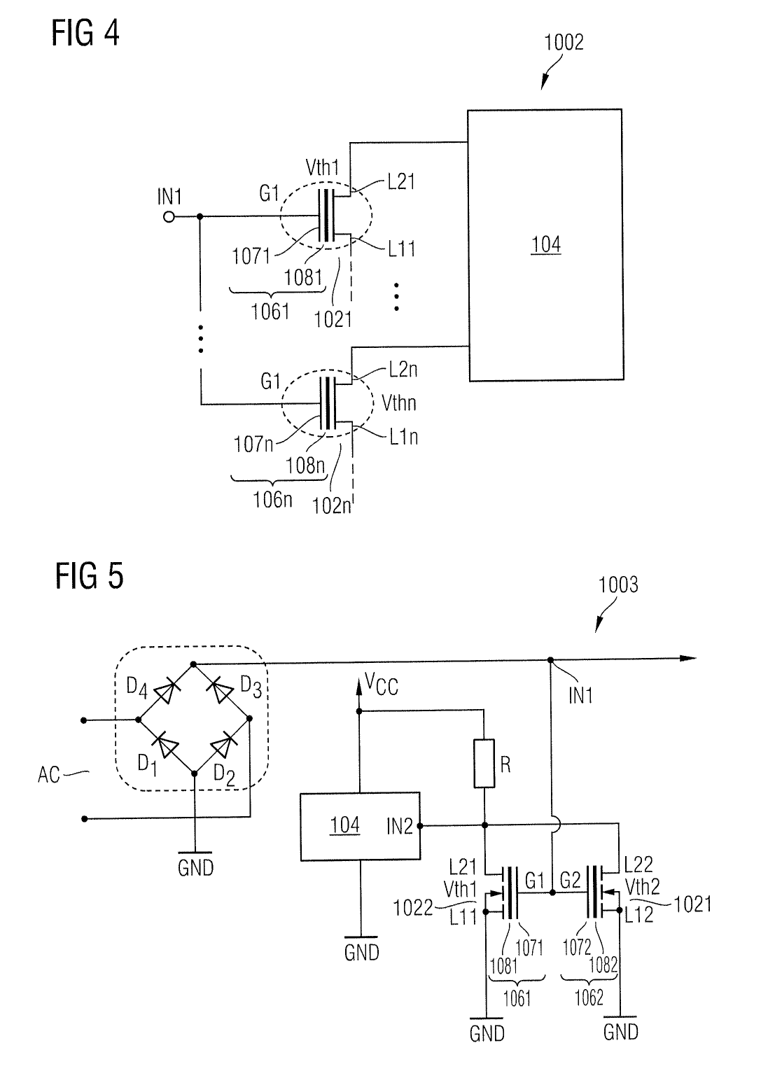

Another embodiment of an electronic circuit 1002 is schematically illustrated in FIG. 4. The electronic circuit 1002 comprises a plurality of input insulated gate field effect transistors 1021 . . . 102n, n>1 comprising first and second load terminals L11 . . . L1n, L21 . . . L2n and control terminals G1 . . . Gn, respectively, the control terminals G1 . . . Gn of the plurality of input insulated gate field effect transistors 1021 . . . 102n being electrically coupled to an input signal terminal IN1 of the electronic circuit 1002. According to an embodiment, the electronic circuit 1002 is an analog to digital converter. All or some of the control terminals G1 . . . Gn may also be electrically coupled to different input signal terminals, for example.

The electronic circuit 1002 further includes the control circuit 104 electrically coupled to the second load terminals L21 . . . L2n. All, some or none of the second load terminals L21 . . . L2n may be electrically coupled to different inputs of the control circuit 104.

Each of the control terminals G1 . . . Gn is electrically connected to a control structure 1061 . . . 106n comprising a control electrode 1071 . . . 107n and charge storage structure 1081_108n, respectively.

In case of the electronic circuit 1002 is an analog to digital converter, the levels of the analog to digital converter may be distributed similar to a conventional analog to digital converter. According to the embodiment, despite omitting a voltage divider, the input voltages may reach high values, for example at most 40 V, 60V, 80 V, 100 V, 250 V, 500 V, 750 V or 1000 V. The analog to digital converter according to the embodiment allows for a high resolution in any desired voltage range including voltage ranges starting at voltages greater than 0 V. By way of example, voltages around a mean voltage, for example 400 V may be resolved in intervals of one or several 10 V, while voltages in a voltage range below the mean voltage, for example below 350 V may be resolved at higher voltage intervals. Such finer voltage intervals or non-equal voltage intervals may be realized several times up to the maximum input voltage, for example. By way of example, in the voltage ranges between, for example 0 V and 80 V and between 350 V and 450V a voltage resolution may be one or several 10 V while no sampling point lies between 80 V and 350 V. The above voltage values are mere examples for illustration purposes.

Another embodiment of an electronic circuit 1003 is schematically illustrated in FIG. 5. The electronic circuit 1003 is configured for voltage detection at a primary side of a switch-mode power supply (SMPS) or a power factor correction or power factor compensation (PFC) circuit. The switch-mode power supply (SMPS) or the power factor correction or power factor compensation (PFC) circuit includes a rectifier comprising diodes D1 to D4.

The electronic circuit 1003 includes first and second input insulated gate field effect transistors 1021, 1022 having control terminals G1, G2, first and second load terminals L11, L12, L21, L22. Each one one first and second input insulated gate field effect transistors 1021, 1022 includes control structure 1061, 1062 including a control electrode 1071, 1072 and a charge storage structure 1081, 1082. The second load terminals L21, L22 are electrically connected to an input terminal IN2 of the control circuit 104. The first and second input insulated gate field effect transistors 1021, 1022 have different threshold voltages Vth1, Vth2. Thereby, a high-voltage window comparator is realized having an overvoltage threshold corresponding to the higher one of Vth1, Vth2 and an undervoltage threshold corresponding to the lower one of Vth1, Vth2.

The electronic circuit 1003 illustrated in FIG. 5 provides the benefit of active current-free detection of high voltage thresholds such as high voltages in semiconductor technologies, for example voltages greater than 40 V, 60V, 80 V, 100 V, 250 V, 500 V, 750 V, 1000 V. Merely a small idle current flows to the control electrodes 1071, 1072 of the input insulated gate field effect transistors 1021, 1022.

In case that a resistance of a resistor R electrically coupled between the input terminal IN2 of the control circuit 104 and a reference voltage terminal VCC is chosen similar to an on-state resistance of each one of the input insulated gate field effect transistors 1021, 1022, a voltage VCC/2 is applied to the input terminal IN2 of the control circuit 104 when one of the input insulated gate field effect transistors 1021, 1022 is turned on. When both input insulated gate field effect transistors 1021, 1022 are turned on, the voltage applied to the input terminal IN2 of the control circuit 104 is VCC/3. Further input insulated gate field effect transistors and/or input insulated gate field effect transistors having different on-state resistance may be arranged to discriminate a signal at the terminal AC or the rectified value at IN1 in a desired way. According to an embodiment, the resistor R and the input insulated gate field effect transistors 1021, 1022 are not monolithically integrated. According to another embodiment, the resistor and the input insulated gate field effect transistors 1021, 1022 are monolithically integrated.

This allows for an improved parameter matching between the resistor R and the input insulated gate field effect transistors 1021, 1022, for example.

Similar to FIG. 3 and not shown in FIG. 5 optional capacitors may be placed in parallel to the control terminals G1, G2, and first load terminals L11, L12 which may serve to filter the input signal in combination with at least one further optional filter resistor connected between the input terminal IN1 and the control terminals G1, G2. Optionally, a series resistor similar to RF in FIG. 3 may be added to the control terminal(s). In one embodiment, the control terminals G1, G2 of the input insulated gate field effect transistors 1021 and 1022 are connected together. In another embodiment, each of the control terminals G1, G2 of the input insulated gate field effect transistors 1021 and 1022 can be connected to the input terminal IN1 via independent resistors to obtain different filter characteristics for the different thresholds.

The electronic circuits described herein allow for benefits such as active current-free detection of voltage thresholds in voltage ranges above 100V or even above 1000V other than resistive dividers and also do not suffer from time-conditioned drawbacks of capacitive dividers.

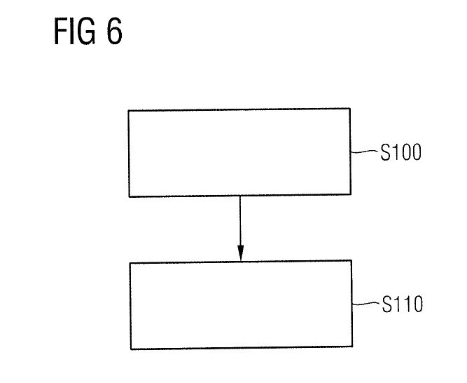

In the figures the first conductivity type is depicted as an “n”-doping while the second conductivity type is depicted as “p”-doping. But this is only an example for explanation purposes. It should be noted that the first conductivity type also may be chosen as an “p”-doping while the second conductivity type may be chosen as “n”-doping. A method of evaluating an input voltage signal is schematically illustrated in FIG. 6.

Method feature 5100 comprises detecting the input voltage signal active current-free by applying the input voltage signal to a control terminal of at least one input insulated gate field effect transistor, wherein a control structure of the least one input insulated gate field effect transistor comprises a control electrode and charge storage structure.

Method feature 5110 comprises supplying a control circuit with a signal at the load terminal of the at least one input insulated gate field effect transistor.

Embodiments of the input insulated gate field effect transistor and the control circuit are described above.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An electronic circuit, comprising:
an input insulated gate field effect transistor comprising first and second load terminals and a control terminal, the control terminal being electrically coupled to an input signal terminal of the electronic circuit;
a control circuit, wherein an input terminal of the control circuit is electrically coupled to the second load terminal; and wherein
the control terminal is electrically connected to a control structure comprising a control electrode and charge storage structure.

2. The electronic circuit of claim 1, wherein the electronic circuit is configured to perform active current-free voltage detection by applying an input voltage signal to the control terminal of the insulated gate field effect transistor.

3. The electronic circuit of claim 1, wherein the input insulated gate field effect transistor is a normally off n-type channel insulated gate field effect transistor.

4. The electronic circuit of claim 1, wherein a threshold voltage of the input insulated gate field effect transistor is at least 10 times greater than a threshold voltage of an insulated gate field effect transistor of the control circuit.

5. The electronic circuit of claim 1, wherein the input insulated gate field effect transistor and the control circuit are monolithically integrated.

6. The electronic circuit of claim 1, wherein a threshold voltage Vth of the input insulated gate field effect transistor is greater than 40 V.

7. The electronic circuit of claim 1, wherein a tunnel dielectric is arranged between the charge storage structure and a semiconductor body comprising a source region and a drain region of the input insulated gate field effect transistor, and a gate dielectric is arranged between the control electrode and the charge storage structure.

8. The electronic circuit of claim 7, wherein a thickness of the tunnel dielectric ranges between 3 nm and 15 nm, and a thickness of the gate dielectric ranges between 150 nm and 30 μm.

9. The electronic circuit of claim 7, wherein the charge storage structure is one of a floating gate electrode and a silicon nitride layer.

10. An electronic circuit, comprising:
a plurality of input insulated gate field effect transistors, each comprising first and second load terminals and a control terminal, the control terminals of the plurality of input insulated gate field effect transistors being electrically coupled to an input signal terminal of the electronic circuit;
a control circuit electrically coupled to the second load terminals; and wherein
each of the control terminals is electrically connected to a control structure comprising a control electrode and charge storage structure.

11. The electronic circuit of claim 10, comprising an analog to digital converter having non-equidistant voltage levels.

12. The electronic circuit of claim 10, wherein the second load terminals are electrically connected to one input terminal of the control circuit.

13. The electronic circuit of claim 10, wherein the control circuit includes different input terminals for each of the second load terminals.

14. The electronic circuit of claim 10, wherein the first load terminals of the plurality of input insulated gate field effect transistors are electrically connected to one reference voltage contact.

15. A range comparator circuit comprising the electronic circuit of claim 10.

16. An analog to digital converter comprising the electronic circuit of claim 1.

17. A method of evaluating an input voltage signal, comprising:
detecting the input voltage signal active current-free by applying the input voltage signal to a control terminal of at least one input insulated gate field effect transistor, wherein a control structure of the least one input insulated gate field effect transistor comprises a control electrode and charge storage structure; and
supplying a control circuit with a signal at the load terminal of the at least one input insulated gate field effect transistor.
